(19) United States
(12) Patent Application Publication
(10) Pub. No.: US 2011/0256657 A1
(43) Pub. Date: Oct. 20, 2011

(54) METHOD OF ENCAPSULATING PHOTOVOLTAIC PANEL

(75) Inventors: Wei-Lun HSIAO, Taoyuan County (TW); Hsiang-Yi YU, Taoyuan Coutny (TW); Hsuan-Ping CHEN, Kaohsiung County (TW)

(73) Assignee: Du Pont Apollo Limited, Hong Kong (HK)

(21) Appl. No.: 13/089,264

(22) Filed: Apr. 18, 2011

Related U.S. Application Data
(60) Provisional application No. 61/325,802, filed on Apr. 19, 2010.

(51) Int. Cl. H01L 31/0203

(52) U.S. Cl. 438/64; 257/E31.117

(57) ABSTRACT

Melted encapsulant is extruded directly onto the photovoltaic panel to encapsulate a photovoltaic panel.

### RELATED APPLICATIONS

This application claims priority to U.S. Provisional Application Ser. No. 61/325,802, filed Apr. 19, 2010, which is herein incorporated by reference.

### BACKGROUND

1. Technical Field

The disclosure relates to photovoltaic panel. More particularly, the disclosure relates to a method of fabricating photovoltaic panels.

2. Description of Related Art

Encapsulant is usually processed to form encapsulation films before used to encapsulate photovoltaic panels in the present encapsulating process. However, in order to control the uniformity of film thickness or to fit the size of the photovoltaic panels, some portions of films are often cut out. Furthermore, the storage life of the encapsulation film is often less than a half year. Therefore, both wastage and storage problems are considerable.

### SUMMARY

The problems of using encapsulant films to encapsulate photovoltaic panels are solved by using melted encapsulant to directly encapsulate the photovoltaic panels in this invention.

According to an embodiment, grains of encapsulant material is first melted and blended in an extruder. The melted and blended encapsulant is then stands still for a period of time for aging. Next, the uniformly blended encapsulant is extruded onto photovoltaic cells to form an encapsulation film. Finally, a backsheet is laminated on the encapsulation film to finish the encapsulating process of the photovoltaic panel.

Since the encapsulant does not need to be pre-processed to form films, both wastage and storage problems above can be solved.

It is to be understood that both the foregoing general description and the following detailed description are by examples, and are intended to provide further explanation of the invention as claimed.

### BRIEF DESCRIPTION OF THE DRAWINGS

FIG. 1 is a side-view diagram of an extruder extruding melted and blended encapsulant onto a photovoltaic panel according to an embodiment of this invention.

### DETAILED DESCRIPTION

In the following detailed description, for purposes of explanation, numerous specific details are set forth in order to provide a thorough understanding of the disclosed embodiments. It will be apparent, however, that one or more embodiments may be practiced without these specific details. In other instances, well-known structures and devices are schematically shown in order to simplify the drawing.

As stated above, encapsulant is usually processed to form encapsulation films before used to encapsulate photovoltaic panels in the present encapsulation process. The process of fabricating encapsulation film may include blending, standing still, calendering or casting, patterning, cooling, edge-cutting, sheet-cutting, and packing. When the encapsulation film is used to encapsulate photovoltaic panels, the encapsulating process may include sealing off, cutting, layup, and laminating. Therefore, the fabricating process of the encapsulation films and the encapsulating process of using the encapsulation films involved many process steps, which usually cause longer process time and higher process cost.

Moreover, in order to control the uniformity of film thickness or to fit the is size of the photovoltaic panels, some portions of films are often cut out to result in wastage problem. The storage life of the encapsulation film is usually less than a half year, which makes the wastage problem more significant and creates storage problem.

In this invention, the fabricating process of the encapsulation films and the encapsulating process of using the encapsulation films have been improved by extruding melted encapsulant directly onto photovoltaic panels to considerably simplify the processes above and solve the problems above.

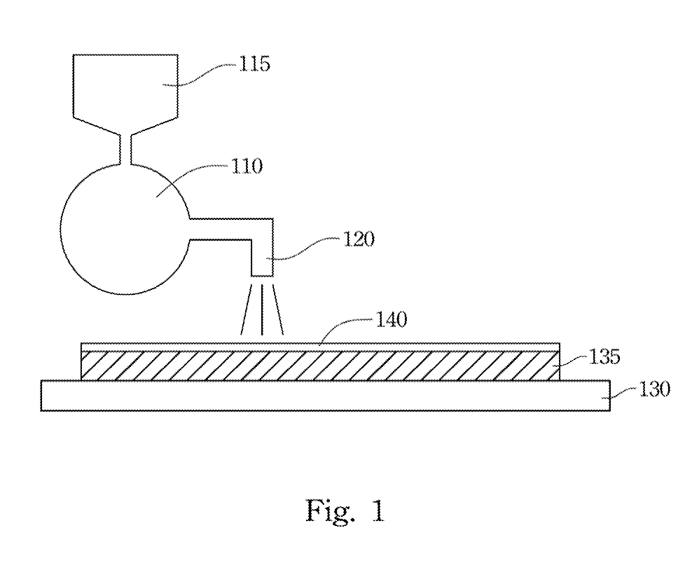

FIG. 1 is a side-view diagram of an extruder extruding melted and blended encapsulant onto a photovoltaic panel according to an embodiment of this invention. First, the encapsulation grains and additives are mixed well in a barrel and then the mixture (i.e. the encapsulant) stands still for a period of time for aging. After that, the encapsulant is fed into the feeder 115 shown in FIG. 1. In FIG. 1, the encapsulant is then melted and blended in an extruder 110 connected to feeder 115.

Next, the melted and well-blended encapsulant is extruded through a nozzle 120, which is connected to the extruder 110, directly onto a photovoltaic panel 135 on a conveyor 130 to form an encapsulation film 140 covering the photovoltaic panel 135. The number of the nozzle 120 can be single or plural as needed. The shape of the nozzle 120 can be circle, strip, or other suitable shapes. There can be relative motion between the positions of the nozzle 120 and the photovoltaic panel 135 to shorten the process time. The encapsulant above can be polyvinyl butyral (PVB), ethylene vinyl acetate (EVA), other suitable materials, or a combination thereof, for example. The thickness of the encapsulation film 140 can be 0.3-1 mm, for example.

Then, a backsheet (not shown in FIG. 1) is placed on the encapsulation film 140. After that, a lamination process is performed to laminate the photovoltaic panel 135, the encapsulation film 140 and the backsheet.

Accordingly, since the melted encapsulant is extruded directly onto the photovoltaic panel to form the encapsulation film, several advantages can be obtained. First, the fabricating process of encapsulation film above can be omitted. Second, the steps of sealing off and cutting in the existing encapsulating process can be further omitted. Third, both the wastage and the storage problem can be solved.

The reader's attention is directed to all papers and documents which are filed concurrently with this specification and which are open to public inspection with this specification, and the contents of all such papers and documents are incorporated herein by reference.

All the features disclosed in this specification (including any accompanying claims, abstract, and drawings) may be replaced by alternative features serving the same, equivalent or similar purpose, unless expressly stated otherwise. Thus, each feature disclosed is one example only of a generic series of equivalent or similar features.

What is claimed is:

1. A process for encapsulating a photovoltaic panel, comprising:
extruding melted encapsulant directly onto the photovoltaic panel with active layers to form an encapsulation film covering the photovoltaic panel; and
laminating a backsheet on the encapsulation film.

2. The process of claim 1, wherein the encapsulant is polyvinyl butyral, ethylene vinyl acetate, or a combination thereof.

3. The process of claim 1, wherein the encapsulation film has a thickness of 0.3-1 mm.

4. A process for encapsulating a photovoltaic panel, comprising:
melting and blending at least an encapsulant in an extruder;
extruding the melted and blended encapsulant directly on the photovoltaic panel through at least a nozzle to form an encapsulation film covering the photovoltaic panel;
laminating a backsheet on the encapsulation film.

5. The process of claim 4, wherein the encapsulant is polyvinyl butyral, ethylene vinyl acetate, or a combination thereof.

6. The process of claim 4, wherein the encapsulation film has a thickness of 0.3-1 mm.

7. The process of claim 4, wherein there is a relative motion between the nozzle and the photovoltaic panel.
